(19) United States
(12) Patent Application Publication
(10) Pub. No.: US 2004/0016935 A1
(43) Pub. Date: Jan. 29, 2004

(54) Charge coupled device

(75) Inventors: Mutsumi Kubota, Hyogo (JP); Masatoshi Kimura, Hyogo (JP)

Correspondence Address: LEYDIG VOIT & MAYER, LTD, 700 THIRTEENTH ST. NW, SUITE 300, WASHINGTON, DC, 20005-3960, US

(73) Assignees: Mitsubishi Denki Kabushiki Kaisha, Tokyo (JP); Ryoden Semiconductor System Engineering Corporation, Itami-shi (JP)

(21) Appl. No.: 10/290,329

(22) Filed: Nov. 8, 2002

(30) Foreign Application Priority Data
Jul. 29, 2002 (JP) 2002-220024

(51) Int. Cl. H01L 33/00

(52) U.S. Cl. 257/98

(57) ABSTRACT

A metal wiring layer, a plurality of metal plugs, a metal wiring layer, a plurality of metal plugs, a metal wiring layer, a plurality of metal plugs and a metal wiring layer are provided so as to surround a space located in the direction perpendicular to a main surface of a semiconductor substrate of a photoelectric conversion element. These metal parts form a light path. The light path reflects incident light which is entered from outside, thereby preventing the incident light from leaking to other photoelectric conversion elements. Therefore, it is possible to obtain a charge coupled device in which the disadvantage of color dispersion and color blurring between pixels adjacent to each other is suppressed.

### BACKGROUND OF THE INVENTION

1. Field of the Invention

The present invention relates to a charge coupled device (solid state image sensor) having a photoelectric conversion (to convert light into charge) element.

2. Description of the Background Art

A charge coupled device having a photoelectric conversion element has been in conventional use. In the following, a conventional charge coupled device having a photoelectric conversion element will be described.

FIG. 13 is a diagram showing a circuit configuration of a charge coupled device provided with CMOS (Complementary Metal Oxide Semiconductor)-type image sensors. As shown in FIG. 13, unit pixels or unit cells C are arranged in a matrix form in the charge coupled device. In addition, each of unit cells C is connected to a vertical shift register VS and to a horizontal shift register HS in the charge coupled device.

Each unit cell C has a photodiode PD, a transfer switch M1, a reset switch M2, an amplifier M3 and a selection switch M4. Photodiode PD converts incident light into a charge and has a function corresponding to that of a photoelectric conversion and storage part for storing the charge that has been converted. Transfer switch M1 has a function of transferring this converted charge to amplifier M3.

Control of transfer switch M1 is carried out by a signal from vertical shift register VS. Reset switch M2 has a function of resetting photodiode PD by allowing the stored charge to flow into the ground electrode. Amplifier M3 has a function of amplification of the magnitude of an electrical signal that has been generated through the transfer of a charge. Selection switch M4 outputs an electrical signal to the outside by means of conduction between the source region and the drain region in the case that selection switch M4 is selected by the vertical shift register and the horizontal shift register.

Here, each of transfer switch M1, reset switch M2, amplifier M3 and selection switch M4 is formed with a MOS transistor.

FIG. 14 is a top view concretely showing a configuration of a region R in FIG. 13. In addition, FIG. 15 is a cross sectional view along the cross sectional line XV-XV of FIG. 14.

As shown in FIGS. 14 and 15, an element isolation insulating film 103 is formed by means of a LOCOS (LOCal Oxidation of Silicon) method in the surface of a P-type semiconductor substrate 102. Furthermore, photodiode PD, transfer switch M1 and reset switch M2 are arranged side-by-side in the surface of P-type semiconductor substrate 102.

Photodiode PD is formed of a PN junction between P-type semiconductor substrate 102 and an N-type impurity diffusion region (N-type active region) 104. Then a P-type impurity diffusion region (P-type active region) 105 is formed in the upper portion (vicinity of the surface of P-type semiconductor substrate 102) of N-type impurity diffusion region 15 104. This P-type impurity diffusion region 105 is formed to have a depth such that the depletion layer of the PN junction between P-type semiconductor substrate 102 and N-type impurity diffusion region 104 does not reach to the bottom surface of P-type impurity diffusion region 105.

Transfer switch M1 has N-type source region 104, an N-type drain region (N-type active region that, in some cases, becomes of the floating condition during operation and, therefore, is represented as FD: Floating Diffusion) 106a and a gate electrode layer 108a. N-type source region 104 and N-type drain region 106a are formed within P-type semiconductor substrate 102 so as to be at a predetermined distance away from each other. Gate electrode layer 108a is formed on top of a gate insulating layer 107 located on the top side of the portion placed between N-type source region 104 and N-type drain region 106a within P-type semiconductor substrate 102.

Here, N-type impurity diffusion region 104 of photodiode PD and N-type source region 104 of transfer switch M1 are the same region, which is referred to separately from the point of view of the respective elements.

Reset switch M2 has a pair of N-type source/drain regions 106a and a gate electrode layer 108b. The pair of N-type source/drain regions 106a is formed in the surface of semiconductor substrate 102 so as to be separated at a predetermined distance away from each other. Gate electrode layer 108b is formed above the region located between the pair of N-type source/drain regions 106a with a gate insulating layer (not shown) intervened there between.

Here, N-type drain region 106a of transfer switch M1 and one of N-type source/drain regions 106a of reset switch M2 are the same region, which is merely referred to separately from the point of view of the respective elements.

In the above described charge coupled device, however, a space located in a direction perpendicular to the main surface of P-type semiconductor substrate 102 of N-type impurity region 104 of photodiode PD is not surrounded by anything. Therefore, the entirety of the light that has entered into the photodiode PD, which is a pixel, does not enter into N-type impurity region 104 of photodiode PD. That is to say, a portion of the light from among the light that has entered into photodiode PD, which is a pixel, enters into N-type impurity diffusion region 104 of another photodiode PD that is adjacent to N-type impurity diffusion region 104 of photodiode PD. Therefore, in some cases, color dispersion and color blurring generate between pixels adjacent to each other.

### SUMMARY OF THE INVENTION

An object of the present invention is to provide a charge coupled device in which the disadvantage of color dispersion and color blurring between pixels adjacent to each other is suppressed.

A charge coupled device according to one aspect of the present invention includes a photoelectric conversion element provided within a semiconductor substrate, and a light path provided on an upper side of the semiconductor substrate so as to extend in the direction perpendicular to a main surface of the semiconductor substrate, for reflecting incident light entered the main surface of the semiconductor substrate, thereby leading the incident light to the photoelectric conversion element.

According to the above described configuration, light to be entered one photoelectric conversion element is prevented from entering other photoelectric conversion elements provided around the one photoelectric conversion element. As a result, the disadvantage of color dispersion and color blurring between pixels adjacent to each other can be suppressed.

A charge coupled device according to another aspect of the present invention includes a photoelectric conversion element provided within a semiconductor substrate, and a light reflection part provided within the semiconductor substrate so as to surround the periphery, around the sides, of the photoelectric conversion element.

According to the above described configuration, light entered one photoelectric conversion element is prevented from escaping to other photoelectric conversion elements provided adjacent to the one photoelectric conversion element within the semiconductor substrate. As a result, the disadvantage of color dispersion and color blurring between pixels adjacent to each other can be suppressed. Noted that a metal may be used for the light reflection part.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view for describing the cross sectional structure of the charge coupled device of a first embodiment;

FIG. 2 is a view for describing the cross section along line II-II of FIG. 1;

FIG. 3 is a view for describing the planar structure of the charge coupled device of a second embodiment;

FIG. 4 is a view for describing the planar structure of the charge coupled device of a third embodiment;

FIG. 5 is a view for describing the cross sectional structure of the charge coupled device of a fourth embodiment;

FIG. 6 is a view for describing the cross sectional structure of the charge coupled device of a fifth embodiment;

FIG. 7 is a view for describing the cross sectional structure of the charge coupled device of a sixth embodiment;

FIG. 8 is a view for describing the cross sectional structure of a charge coupled device of a seventh embodiment;

FIG. 9 is a view for describing the cross sectional structure of another charge coupled device of the seventh embodiment;

FIG. 10 is a view for describing the cross sectional structure of the charge coupled device of an eighth embodiment;

FIG. 11 is a view for describing the planar structure of the charge coupled device of a ninth embodiment;

FIG. 12 is a view for describing the planar structure of the charge coupled device of a tenth embodiment;

FIG. 13 is a diagram for describing the circuit configuration of a charge coupled device;

FIG. 14 is a view for describing the planar structure focusing on one pixel portion of a charge coupled device; and

FIG. 15 is a view showing the cross section along line XV-XV of FIG. 14.

### DESCRIPTION OF THE PREFERRED EMBODIMENTS

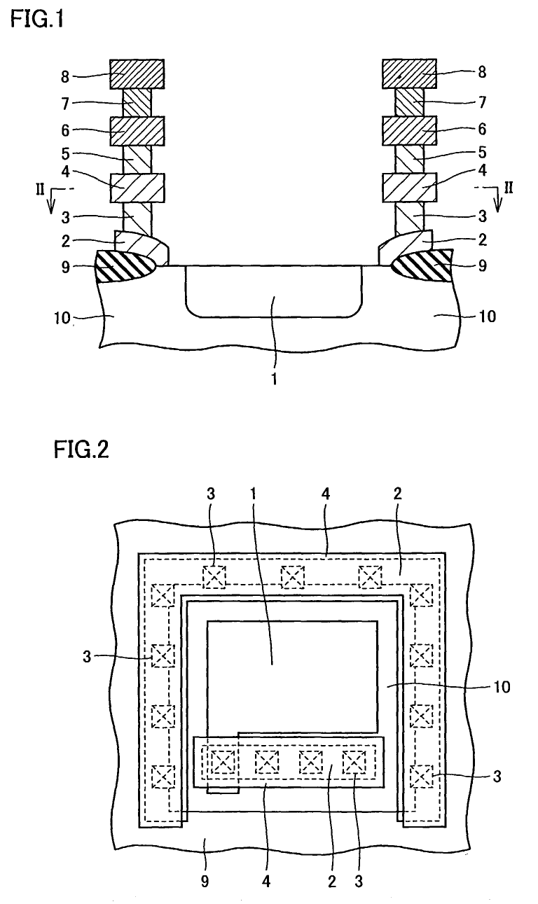

In the following the charge coupled devices according to the embodiments of the present invention are described with reference to FIGS. 1 to 12.

First Embodiment

First, the charge coupled device of a first embodiment will be described with reference to FIGS. 1 and 2. A photoelectric conversion element 1 is formed from the main surface down to a predetermined depth in a semiconductor substrate 10 in the charge coupled device of the present embodiment, as shown in FIGS. 1 and 2. As viewed from the direction perpendicular to the main surface of semiconductor substrate 10, as shown in FIG. 2, an element isolation insulating film 9 is provided so as to surround photoelectric conversion element 1.

In addition, a metal wiring layer 2 is provided on the top side of element isolation insulating film 9 and of semiconductor substrate 10. This metal wiring layer 2 is formed so as to surround photoelectric conversion element 1, as viewed from the direction perpendicular to the main surface of semiconductor substrate 10, in the same manner as for element isolation insulating film 9. In addition, a plurality of metal plugs 3 is formed on top of metal wiring layer 2. This plurality of metal plugs 3 is formed so as to surround photoelectric conversion element 1 and so as to have equal intervals, as viewed from the direction perpendicular to the main surface of semiconductor substrate 10. In addition, a metal wiring layer 4 is connected to the respective top edges of the plurality of metal plugs 3.

This metal wiring layer 4 is formed so as to surround photoelectric conversion element 1, as viewed from the direction perpendicular to the main surface of semiconductor substrate 10, in the same manner as for metal wiring layer 2. In addition, a plurality of metal plugs 5 is formed on top of metal wiring layer 4. This plurality of metal plugs 5 is formed so as to surround photoelectric conversion element 1 and so as to have equal intervals, as viewed from the direction perpendicular to the main surface of semiconductor substrate 10. In addition, a metal wiring layer 6 is connected to the respective top edges of the plurality of metal plugs 5.

Metal wiring layer 6 is formed so as to surround photoelectric conversion element 1, as viewed from the direction perpendicular to the main surface of semiconductor substrate 10. In addition, a plurality of metal plugs 7 is formed on the top side of metal wiring layer 6. This plurality of metal plugs 7 is formed so as to surround photoelectric conversion element 1 and so as to have equal intervals, as viewed from the direction perpendicular to the main surface of semiconductor substrate 10. In addition, a metal wiring layer 8 is connected to the respective top edges of the plurality of metal plugs 7. This metal wiring layer 8 is provided so as to surround photoelectric conversion element 1, as viewed from the direction perpendicular to the main surface of semiconductor substrate 10.

According to the charge coupled device of the present embodiment having the above described configuration, a light path for leading light that has entered in the direction perpendicular to the main surface of the semiconductor substrate to photoelectric conversion element 1 is formed of metal wiring layer 2, the plurality of metal plugs 3, metal wiring layer 4, the plurality of metal plugs 5, metal wiring layer 6, the plurality of metal plugs 7 and metal wiring layer 8. Here, it is desirable for the intervals among the plurality of metal plugs 3, the plurality of metal plugs 5 and plurality of metal plugs 7 to be as narrow as possible and for the respective heights of the plurality of metal plugs 3, the plurality of metal plugs 5 and plurality of metal plugs 7 to be as low as possible so that the gaps between the light paths become as small as possible.

As large an amount of light as possible is led to photoelectric conversion element 1 through the reflection of the light that has entered so as not to allow the light to escape to other areas from the surfaces inside of this light path. That is to say, this light path makes it possible to prevent the escape, to other photoelectric conversion elements, of the light that has entered into photoelectric conversion element 1. As a result, a charge coupled device is formed wherein the generation of color dispersion and color blurring between pixels adjacent to each other is prevented.

Here the light path includes metal plugs 3, 5 and 7 as vertical metal parts extending in the direction perpendicular to semiconductor substrate 10 as well as metal wiring layers 2, 4, 6 and 8 as horizontal metal parts extending in the direction parallel to semiconductor substrate 10 and, therefore, the vertical metal parts and the horizontal metal parts used for the light path can be simultaneously formed as vertical metal parts and horizontal metal parts used for other elements.

Second Embodiment

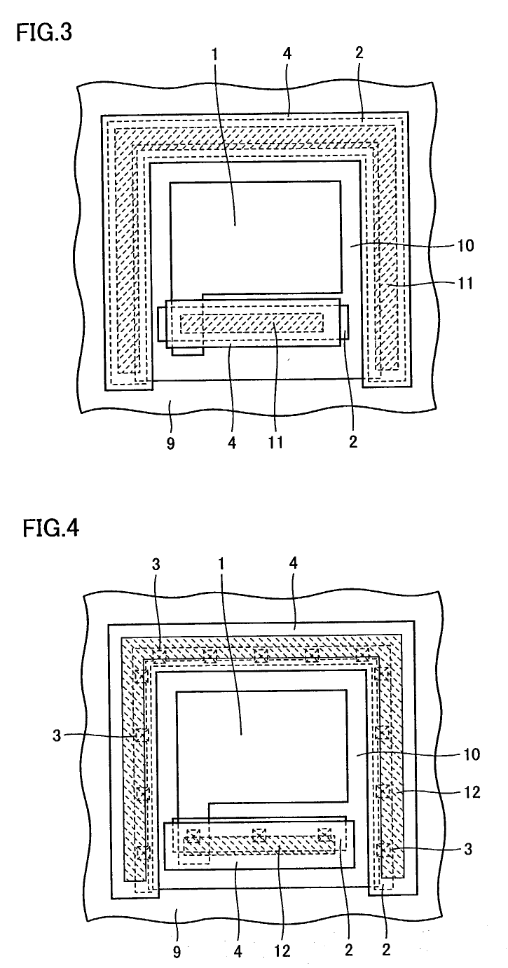

Next, the charge coupled device of a second embodiment will be described with reference to FIG. 3. The charge coupled device of the present embodiment has approximately the same structure as the structure of the charge coupled device of the first embodiment. The charge coupled device of the present embodiment is provided with metal walls 11 in place of metal plugs 3 of the charge coupled device of the first embodiment. Metal walls 11 of the charge coupled device of the present embodiment differs from the plurality of metal plugs 3 shown in FIGS. 1 and 2 and does not have gaps such as those between metal plugs 3, adjacent to each other.

Therefore, according to the charge coupled device of the present embodiment, the light that has entered into photoelectric conversion element 1 can be prevented from escaping to other photoelectric conversion elements to a greater extent. As a result, according to the charge coupled device of the present embodiment it becomes possible to suppress the generation of color dispersion and color blurring between pixels to a greater extent than in the charge coupled device of the first embodiment.

Third Embodiment

Next, the charge coupled device of a third embodiment will be described with reference to FIG. 4. The charge coupled device of the third embodiment has approximately the same structure as the structure of the charge coupled device of the first or second embodiment. The metal plugs 3 of the charge coupled device of the first embodiment are used without change in the charge coupled device of the present embodiment and a metal wall 12 in the same form as metal wall 11 of the second embodiment is used in place of metal plugs 5 of the first embodiment.

That is to say, the charge coupled device of the present embodiment has a structure wherein a plurality of metal plugs such as that used in the first embodiment and metal walls such as those used in the second embodiment are used together. In the charge coupled device of the present embodiment it is also possible to suppress the generation of color dispersion between pixels of the charge coupled device and color blurring of the charge coupled device in the same manner as in the first and second embodiments.

Fourth Embodiment

Next, the charge coupled device of a fourth embodiment will be described with reference to FIG. 5. The charge coupled device of the present embodiment has approximately the same structure as the charge coupled device of the first embodiment. The charge coupled device of the present embodiment differs from the charge coupled device of the first embodiment solely in that metal wiring layer 2 has a greater height than metal wiring layer 2 of the first embodiment.

By having such a structure, the incident light can be prevented from escaping, in the vicinity of the main surface of semiconductor substrate 10, toward other photoelectric conversion elements to a greater extent than in the charge coupled device shown in the first embodiment. Therefore, according to the charge coupled device of the present embodiment, it becomes possible to suppress the generation of color blurring and color dispersion between pixels to a greater extend.

Fifth Embodiment

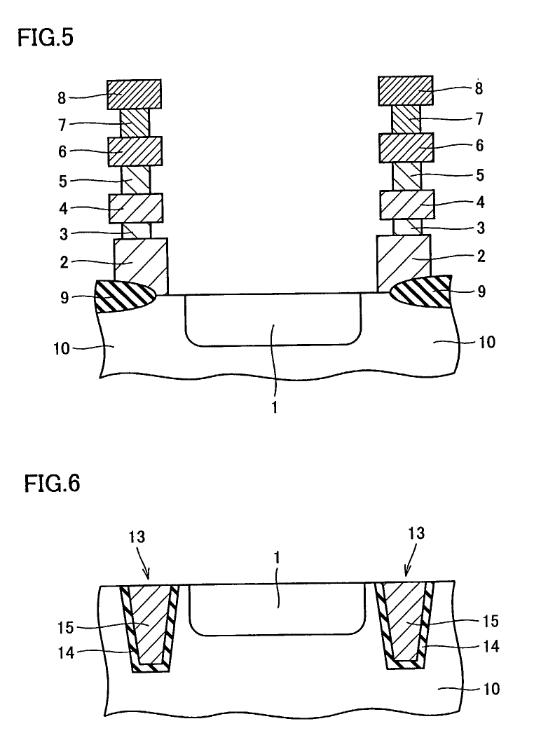

Next, the charge coupled device of a fifth embodiment will be described with reference to FIG. 6. The charge coupled device of the present embodiment is provided with a semiconductor substrate 10, a photoelectric conversion element 1 formed from the main surface of semiconductor substrate 10 down to a predetermined depth and a trench formed so as to surround photoelectric conversion element 1. In addition, the charge coupled device of the present embodiment is provided with an insulating film. 14 provided along the inner sides of the trench and a metal filling portion 15 that is filled in into the inside of the trench having insulating film 14.

Though only the cross sectional structure of the charge coupled device of the present embodiment is described with reference to FIG. 6, the charge coupled device is formed so that insulating film 14 and metal filling portion 5 surround the periphery of photoelectric conversion element 1, as viewed from the direction perpendicular to the main surface of semiconductor substrate 10.

According to the above described charge coupled device of the present embodiment, the light that has entered into photoelectric conversion element 1, which could escape toward other photoelectric conversion elements, is reflected from the inner sides of metal filling portion 15. Therefore, the light that has entered into photoelectric conversion element 1 can be prevented from escaping, within semiconductor substrate 10, toward other photoelectric conversion elements. Therefore, according to the charge coupled device of the present embodiment, color dispersion and color blurring between pixels can be suppressed. In addition, insulating film 14 insulates photoelectric conversion element 1 from metal filling portion 15 so that electrical effects between photoelectric conversion element 1 and metal filling portion 15 are blocked.

Sixth Embodiment

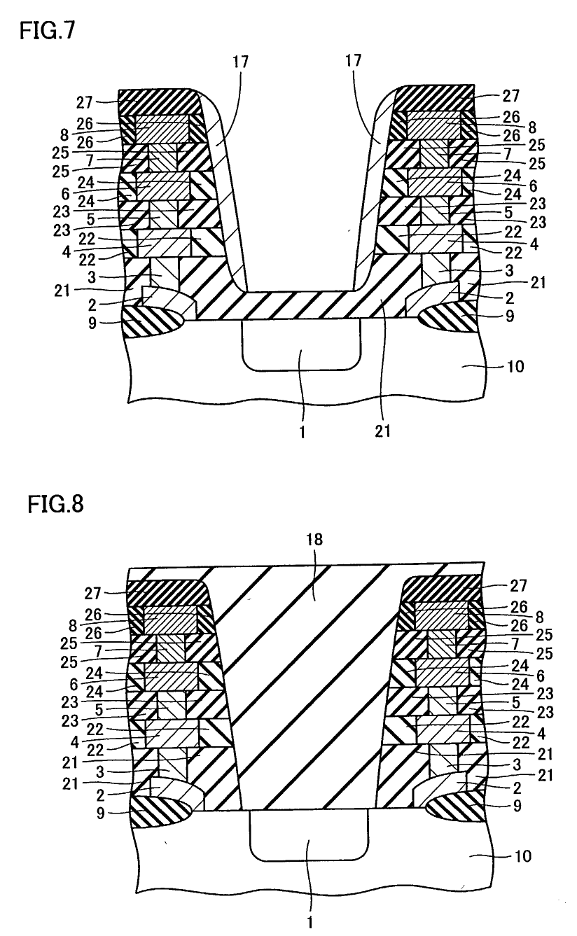

Next, the charge coupled device of a sixth embodiment will be described with reference to FIG. 7. The charge coupled device of the present embodiment is approximately the same as the charge coupled device of the first embodiment, as shown in FIG. 7.

As shown in FIG. 7, the charge coupled device of the present embodiment is provided with a main surface of semiconductor substrate 10, an insulating film 21 into which metal wiring layer 2 and metal plugs 3 are buried, an insulating film 22 into which metal wiring layer 4 is buried, an insulating film 23 into which a plurality of metal plugs 5 is buried, an insulating film 24 into which a metal wiring layer 6 is buried, an insulating film 25 into which a plurality of metal plugs 7 is buried, an insulating film 26 into which a metal wiring layer 8 is buried and insulating film 27 formed on top of metal wiring layer 8.

In addition, insulating film 27, insulating film 26, insulating film 25, insulating film 24, insulating film 23 and insulating film 22 as well as a portion of insulating film 21 are removed above photoelectric conversion element 1 and, as a result, a hole is formed. A metal film 17 is provided on the inner sides of this hole. This metal film 17 is provided so as to surround photoelectric conversion element 1, as viewed from the direction perpendicular to the main surface of semiconductor substrate 10.

According to the charge coupled device of the present embodiment, the provision of metal film 17 prevents the light that has entered from above to photoelectric conversion element 1 from escaping toward photoelectric conversion elements other than photoelectric conversion element 1. Therefore, according to the charge coupled device of the present embodiment, color dispersion and color blurring between pixels can be suppressed.

Here, metal film 17, as a light path, is in the form of a tube and, therefore, can lead light to a specific photoelectric conversion element without fail, without allowing light to escape to other photoelectric conversion elements.

In addition, the area of the opening on the photoelectric conversion element 1 side is smaller than the area of the opening on the light incidence side of tubular metal film 17 and, therefore, it becomes possible to collect a greater amount of light, which is led to photoelectric conversion element 1.

Seventh Embodiment

Next, the charge coupled device of a seventh embodiment will be described with reference to FIG. 8. The charge coupled device of the seventh embodiment has approximately the same structure as the charge coupled device of the sixth embodiment, as shown in FIG. 8. Here, the hole provided in insulating film 27, insulating film 26, insulating film 25, insulating film 24, insulating film 23, insulating film 22 and insulating film 21 exposes the top of photoelectric conversion element 1. In addition, an insulating film 18 made of a single material is filled in into this hole. Here, though the surface of photoelectric conversion element 1 is exposed at the bottom of the hole in the charge coupled device of the present embodiment, a charge coupled device may be provided wherein insulating film 21, having a certain thickness, remains on top of photoelectric conversion element 1.

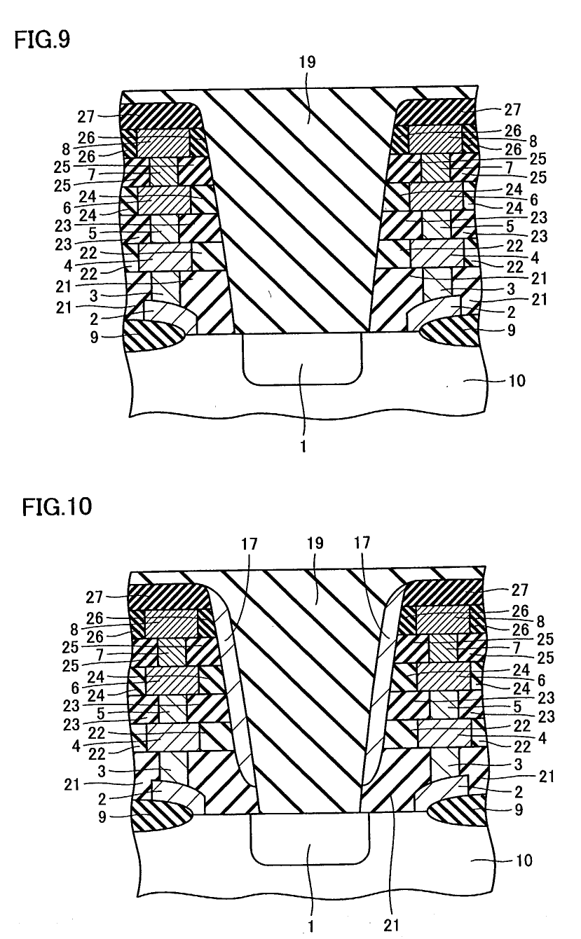

According to the charge coupled device of the present embodiment, insulating film 18, alone, made of a single material, is located before photoelectric conversion element 1 in the incidence path of the light that enters from outside. Therefore, the reflection caused by the difference in the index of refraction among a plurality of layers in a plurality of incidence paths of the light can be prevented. As a result, according to the charge coupled device of the present embodiment, color blurring and color dispersion between pixels can be suppressed to a greater degree than in the conventional charge coupled device. In addition, though insulating film 18 is used in FIG. 8, it is more preferable for this insulating film 18 to be made of silicon oxide film 19 as shown in FIG. 9.

Eighth Embodiment

Next, the charge coupled device of an eighth embodiment will be described with reference to FIG. 10. The charge coupled device of the eighth embodiment has approximately the same structure as the structure of charge coupled device of the sixth embodiment described with reference to FIG. 7 and of the charge coupled device of the seventh embodiment described with reference to FIGS. 8 and 9. In addition, the charge coupled device of the present embodiment is provided with metal film 17, which characterizes the charge coupled device of the sixth embodiment, and with silicon oxide film 19, which characterizes the charge coupled device of the seventh embodiment.

That is to say, metal film 17 is formed in the hole formed by removing insulating film 27, insulating film 26, insulating film 25, insulating film 24, insulating film 23, insulating film 22 and insulating film 21 and, furthermore, silicon oxide film 19, made of a single layer, is filled in into the inside of the hole having metal film 17.

Accordingly, silicon oxide film 19 made of a single layer is formed in the path of the light that has entered from the outside before the light reaches the photoelectric conversion element and, therefore, reflection caused by the existence of a plurality of layers having different indexes of refraction of light is prevented. In addition, reflection of the light that has entered from the inner surfaces of metal film 17 prevents the light that should enter photoelectric conversion element 1 from escaping in the direction toward other photoelectric conversion elements.

Ninth Embodiment

Next, the charge coupled device of a ninth embodiment will be described with reference to FIG. 11. The charge coupled device of the ninth embodiment has approximately the same structure as the charge coupled devices of the first to eighth embodiments. However, metal wiring layer 2 is formed so as not to have a right angled corner, as viewed from the direction perpendicular to the main surface of semiconductor substrate 10.

That is to say, each corner of the rectangles formed by the inner surfaces of light paths as shown in FIGS. 2 to 4 is in the condition of being rounded or/and beveled. As a result, the charge coupled device has a structure wherein metal wiring layer 2, having octagonal inner surfaces, surrounds the periphery of photoelectric conversion element 1 in the cross section parallel to the main surface of semiconductor substrate 10. Inner walls for surrounding photoelectric conversion element 1 are formed solely of corners having obtuse angles, without the use of right angled corners, wherein reflection of light easily generates in the above described manner and, thereby, color dispersion and color blurring between pixels of the charge coupled device can be further suppressed.

Tenth Embodiment

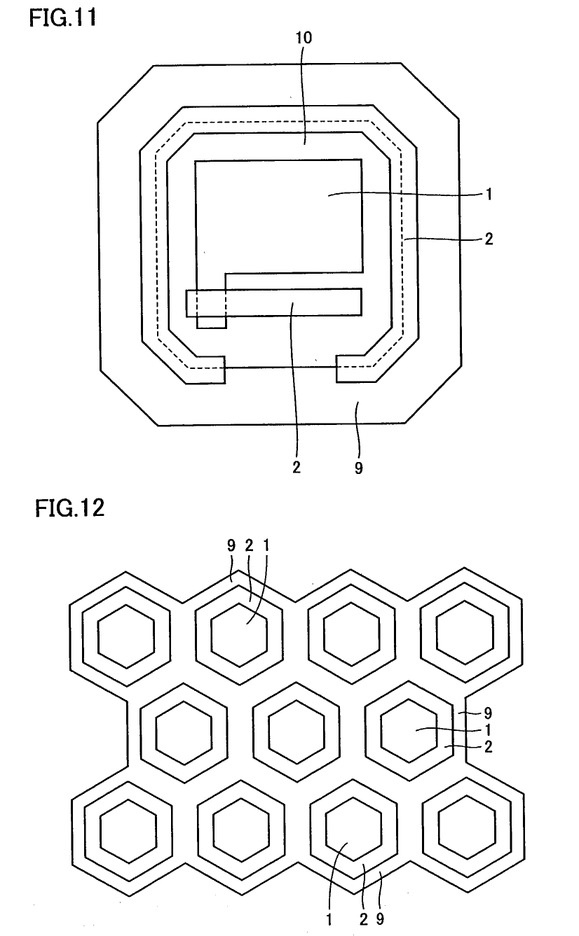

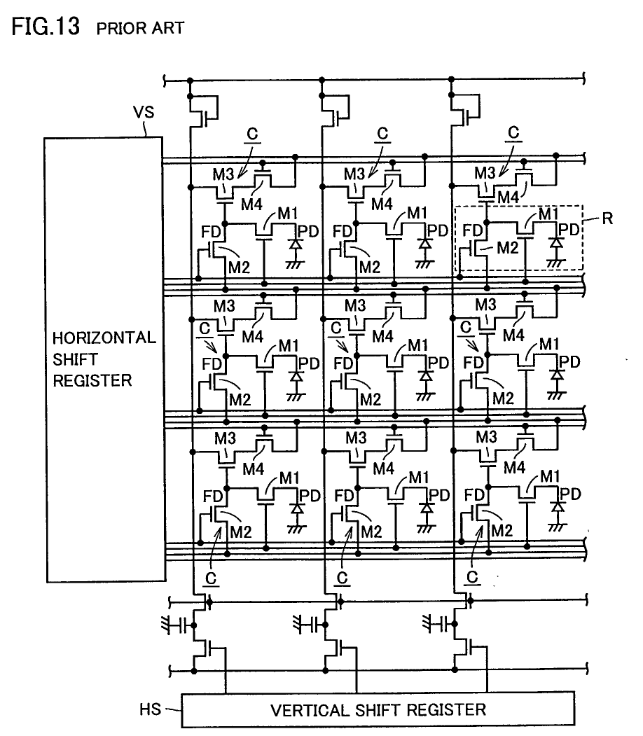

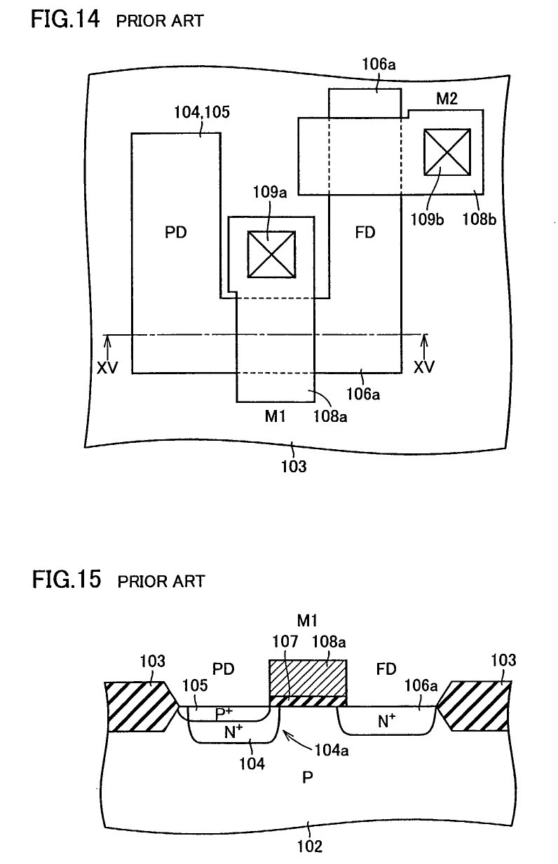

Next, the charge coupled device of a tenth embodiment will be described with reference to FIG. 12. In the charge coupled device of the present embodiment, the form of the outer periphery of photoelectric conversion element 1 is a regular hexagon, as viewed from the direction perpendicular to the main surface of semiconductor substrate 10, and an element isolation insulating film 2, of which the outer periphery and the inner periphery make up regular hexagons, is formed so as to surround the periphery of the above described photoelectric conversion element 1, of a regular hexagonal shape. In addition, in the main surface of semiconductor substrate 1, both the inner periphery surfaces and the outer periphery surfaces of the portion corresponding to the light paths of the charge coupled devices of the first to ninth embodiments are in regular hexagonal shapes, as viewed from the direction perpendicular to the main surface of the semiconductor substrate.

Photoelectric conversion elements 1, as pixels in the direction parallel to the main surface of the semiconductor substrate, can most efficiently be arranged and metal wiring layers 2, as light paths formed above photoelectric conversion elements 1, can also be formed most efficiently from the point of view of the arrangement in the direction parallel to the main surface of the semiconductor substrate by having the above described structure. Accordingly, it becomes possible to reduce the area in the direction parallel to the main surface of the semiconductor substrate of the charge coupled device to the greatest extent.

In addition, the inner sides of metal wiring layer 2, as a light path, are also formed solely of obtuse angles in the charge coupled device of the present embodiment. That is to say, there are no portions wherein the inner periphery sides of the light path have acute angles or right angles. As a result, leakage of incident light to other photoelectric conversion elements, which can generate with right angled corners or obtuse angled corners, can be prevented in the same manner as in the charge coupled device of the ninth embodiment, shown in FIG. 11.

Here, it is possible to get the respective effects gained by the charge coupled devices of the respective embodiments by appropriately combining and using the respective characteristics of the charge coupled devices of the respective embodiments.

In addition, though a metal is used for a light path of the charge coupled device of each of the above described embodiments, another material, other than a metal, may be used as long as the material allows the incident light to be reflected and led to the photoelectric conversion element. In addition, a material such as tungsten silicide may be considered as the metal. In addition, the metal wiring layer may be a gate wire layer. In addition, the metal plugs may be contact holes or via holes (through holes). In addition, the element isolation insulating film may be formed by means of a LOCOS (LOCal Oxidation of Silicon) method or may be formed within a trench.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A charge coupled device comprising:
a photoelectric conversion element provided within a semiconductor substrate; and
a light path, provided on an upper side of said semiconductor substrate so as to extend in the direction perpendicular to a main surface of the semiconductor substrate, for reflecting incident light entered the main surface of the semiconductor substrate, thereby leading the incident light to said photoelectric conversion element.

2. The charge coupled device according to claim 1, wherein
a metal is used for said light path.

3. The charge coupled device according to claim 1, wherein
said light path includes a vertical metal portion extending in the direction perpendicular to said semiconductor substrate and a horizontal metal portion extending in the direction parallel to said semiconductor substrate.

4. The charge coupled device according to claim 1, wherein
said light path has a tubular portion.

5. The charge coupled device according to claim 4, wherein
said tubular portion has an area of an opening on said photoelectric conversion element side smaller than an area of the opening on the light incidence side.

6. The charge coupled device according to claim 1, wherein
a portion that the incident light reaches said photoelectric conversion element from the outside is formed of a single material.

7. The charge coupled device according to claim 1, wherein
the inner sides of said light path are solely formed of at least either of a curve surface or of a plurality of obtuse angles.

8. The charge coupled device according to claim 1, wherein
the inner periphery of said light path is in a regular hexagonal shape in a cross section parallel to the main surface of said semiconductor substrate.

9. The charge coupled device according to claim 1, wherein
the outer periphery of said photoelectric conversion element is in a regular hexagonal shape in a cross section parallel to the main surface of said semiconductor substrate.

10. A charge coupled device comprising:
a photoelectric conversion element provided within a semiconductor substrate; and
a light reflection part provided within said semiconductor substrate so as to surround the periphery, around the sides, of said photoelectric conversion element.

11. The charge coupled device according to claim 10, wherein
a metal is used for said light reflection part.

12. The charge coupled device according to claim 10, wherein
said light reflection part is formed within a trench formed in a main surface of the semiconductor substrate down to a predetermined depth.

13. The charge coupled device according to claim 10, wherein
an insulating film is provided between said light reflection part and said photoelectric conversion element.
